(19) United States
(12) Patent Application Publication
(10) Pub. No.: US 2008/0050681 A1
(43) Pub. Date: Feb. 28, 2008

(54) Immersion fluid for immersion lithography

(75) Inventor: Toshirou Itani, Ibaraki (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 11/892,603

(22) Filed: Aug. 24, 2007

(30) Foreign Application Priority Data
Aug. 28, 2006 (JP) 2006-230725

(51) Int. Cl. G03F 7/20

(52) U.S. Cl. 430/396; 430/461

(57) ABSTRACT

Aimed at improving balance between refractive index and absorbance of an immersion fluid used for light exposure based on the immersion method, the immersion fluid is configured as containing a deuterated dialkyl sulfoxide.

This application is based on Japanese patent application No. 2006-230725 the content of which is incorporated hereinto by reference.

### BACKGROUND

1. Technical Field

The present invention relates to an immersion fluid for immersion lithography, and a method of optical projection lithography using the same.

2. Related Art

Although optical projection lithography equipment based on the step-and-repeat system (stepper) has widely been used as projection exposure equipment for manufacture of semiconductor devices, much attention has recently been focused on step-and-scan-type projection exposure equipment in which a wafer is exposed to light through a reticle while scanning the reticle and the wafer in synchronization with each other.

Resolution of an optical projection system provided to a projection exposure equipment increases as the exposure wavelength to be adopted becomes shorter, and as the numerical aperture of the optical projection system becomes larger. For this reason, the wavelength of exposure adopted by the projection exposure equipment has become shorter year by year, and also the numerical aperture of the optical projection system has become larger, with progress of shrinkage of semiconductor devices. Not only a wavelength of 248 nm of KrF excimer laser, as the mainstream of exposure wavelength at present, also a further-shortened wavelength of 193 nm of ArF excimer laser has been put into practical use.

Under the trends towards shorter wavelength of exposure light, there are only a limited range of glass materials having transmittance capable of ensuring an energy of light sufficient for light exposure, while ensuring a desired level of image quality, a proposal has been made on an immersion projection exposure equipment, in which a space between the final lens of the optical projection system and the wafer surface is filled with a fluid such as water, organic solvent or the like, aimed at improving the resolution based on a knowledge that wavelength of the exposure light in the fluid becomes 1/n times as short as the wavelength attained in the air (Japanese Laid-Open Patent Publication No. H10-303114), where n is refractive index of the fluid.

General requirements for the fluid used for this sort of application are that the absorbance should be as low enough as ensuring a route of beam substantially same for all optical paths, and that the fluid should be excellent in photochemical stability, and that the fluid should have a large refractive index at the wavelength of light exposure.

Carbohydrate and saturated alicyclic hydrocarbon compound have been known as the fluid having large refractive index indices required for immersion lithography. The absorbance of these compounds were, however, large in view of adopting them to immersion lithography, particularly in the wavelength region of 250 nm or shorter.

Other technologies related to the fluid for immersion lithography include those described in Japanese Laid-Open Patent Publication No. 2005-276897, WO2005/006026, and WO 2005/106589.

Of these, Japanese Laid-Open Patent Publication No. 2005-276897 and WO2005/006026 describe use of immersion fluid containing deuterium oxide.

WO 2005/106589 describes use of deuterium oxide, deuterated sulfuric acid, or deuterated phosphoric acid as the immersion fluid.

However, the present inventor has recognized that the technologies described in Japanese Laid-Open Patent Publication No. 2005-276897, WO2005/006026, and WO 2005/106589 still have a room of improvement, from the viewpoints of preparing for the fluid having higher refractive index and lower absorbance with exposure wavelength.

### SUMMARY

After extensive investigations aimed at achieving the above-described objectives, the present inventors found out that the immersion fluid can be well balanced between refractive index and absorbance, by using a deuterated dialkyl sulfoxide which exists as fluid at ordinary temperatures, and thereby completed the present invention.

According to the present invention, there is provided an immersion fluid used for optical projection lithography based on the immersion method, containing a deuterated dialkyl sulfoxide.

Because the immersion fluid for optical projection lithography of the present invention contains a deuterated dialkyl sulfoxide, the refractive index can be raised to a sufficient level, and at the same time, the absorbance at the wavelength of light exposure used can be lowered to a sufficient level. As a consequence, resolution can be improved while ensuring an energy of light sufficient for light exposure.

The immersion fluid for optical projection lithography of the present invention contains a deuterated dialkyl sulfoxide, allowing any other components contained therein only to a range not causative of local variation in the refractive index of the immersion fluid, a factor that may inhibit stable patterning as a consequence.

According to the present invention, there is also provided a method of optical projection lithography irradiating a mask with exposure light and guiding that the light through a fluid medium to the surface of a substrate, thereby transferring a pattern of said mask to the surface of said substrate, wherein the fluid medium is the above-described immersion fluid for immersion lithography of the present invention.

In the present invention, the exposure light is guided to the surface of the substrate through a fluid medium containing a deuterated dialkyl sulfoxide. As a consequence, pattern formation on a substrate with a mask can stably be patterned by immersion lithography with a high resolution.

It is to be understood that any arbitrary combinations of these configurations, and any expressions of the present invention exchanged among the method and equipment and so forth, are valid as embodiments of the present invention.

As has been previously described, the present invention can improve the balance between refractive index and absorbance of the immersion fluid used for immersion lithography.

### DETAILED DESCRIPTION

The invention will now be described herein with reference to an illustrative embodiment. Those skilled in the art will recognize that many alternative embodiments can be accomplished using the teachings of the present invention and that the invention is not limited to the embodiment illustrated for explanatory purposed.

Paragraphs below will describe embodiments of the present invention. The explanation below will place a focus on exemplary cases where the immersion lithography is applied to patterning of a resist film formed on a wafer, wherein the immersion fluid for immersion lithography of the present invention is applicable to any immersion lithography aimed at a variety of materials and applications.

The immersion fluid for immersion lithography of the present invention is an immersion fluid used for immersion lithography, and contains a deuterated dialkyl sulfoxide.

By using a deuterated dialkyl sulfoxide as the immersion fluid for immersion lithography, the refractive index can be increased as comparable to the case where deuterium oxide (D₂O) is used, as described later in Examples. Therefore, depth of focus on the surface of an object to be exposed, such as a wafer, can be increased. Also exposure margin can be increased. For example, the immersion fluid for immersion lithography can be designed to have a refractive index n of 1.6 or larger at 193 nm.

The immersion fluid for immersion lithography of the present invention may be configured as a fluid having substantially no reactivity to light used for light exposure. By this configuration, light exposure can be proceeded in a more stable manner. In addition, for an exemplary case where a resist film provided to the surface of a wafer is exposed, degradation of the resist film can exactly be suppressed. By using deuterated dialkyl sulfoxide as the immersion fluid for immersion lithography, the photo-reactivity can be lowered as compared with compounds having a ring containing unsaturated carbon atoms, such as benzene ring.

The immersion fluid for immersion lithography of the present invention may be given typically as a substantially clear fluid at the wavelength of light exposure. This configuration ensures light exposure in an exact manner. For an exemplary case where a light source used for light exposure is an ArF excimer laser source, transmittance of the immersion fluid, having a thickness of 1 mm, at a wavelength of 193 nm is preferably adjusted to, for example, 90% or above. For another exemplary case where a light source used for light exposure is a KrF excimer laser source, transmittance of the immersion fluid, having a thickness of 1 mm, at a wavelength of 248 nm is preferably adjusted to, for example, 90% or above. For still another exemplary case where a light source used for light exposure is 157 nm F₂ excimer laser source, transmittance of the immersion fluid, having a thickness of 1 mm, at a wavelength of 157 nm is preferably adjusted to, for example, 90% or above. By using deuterated dialkyl sulfoxide as the immersion fluid, the absorbance can be lowered to a sufficient degree, even if the exposure wavelength is short. In other words, the transmittance can sufficiently be increased.

Now, absorbance of the immersion fluid can be measured according to the method described below.

In Examples described later, the absorbance was measured using Model U-2000 double-beam spectrophotometer from Hitachi, Ltd., in the wavelength range from 190 to 250 nm.

A sample diluted with cyclohexane, showing only a small absorption in the wavelength range from 190 to 250 nm, was placed in a square quartz cell ensuring a 1 cm thick sample layer, and absorption was measured. Value of absorbance was calculated by subtracting a value of absorbance obtained for a cell containing only a solvent for dilution, from an experimentally measured value. Molar absorption coefficient ε was calculated according to the Lambert-Beer's equation, using absorbance A determined by the measurement. More specifically, the calculation was made using the equation below:

ε=A/{L(cm)·c(mol/l)}

(where, L represents thickness (cm) of fluid layer in a measurement cell, and c represents concentration of the measured solution).

The sample in this case was kept at room temperature, cooled using liquid nitrogen, and then carefully degassed in vacuo using a mechanical pump (typically at a degree of vacuum of 10⁻³ mbar) so as to purge the dissolved gas. Thus-degassed sample was stored in a small glass vial with an airtight Rotaflo(Registered Trademark) stopcock.

The measurement cell was filled with the sample, and closed in a dry box under nitrogen gas flow, so as to prevent the sample from absorbing the air.

The transmissivity can be calculated according to the equation below:

A(cm⁻¹)=log₁₀(T)/s

(where, T represents transmissivity, and s represents thickness (unit: cm) of a spacer disposed between the windows).

In Example described later, absorbance of the fluid was determined according to this method.

Those existing as liquid at room temperatures (25 degrees centigrade) can be used as the immersion fluid for immersion lithography of the present invention. The immersion fluid for immersion lithography of the present invention may be any fluid having a high boiling point. More specifically, the boiling point of the immersion fluid for immersion lithography may be selected as 50 degrees centigrade or above, and preferably 70 degrees centigrade or above. By this selection, vaporization of the immersion fluid for immersion lithography during light exposure or other operations can be suppressed. As a result, the resist can be patterned by immersion lithography in a stable manner. There is no special limitation on the upper limit of the boiling point of the immersion fluid for immersion lithography, and may be specified as 300 degrees centigrade or below.

The immersion fluid for immersion lithography preferably shows only a small solubility to a film to be illuminated which is brought into contact therewith in the process of light exposure. For an exemplary case of patterning a resist provided to the surface of a wafer, the immersion fluid may be configured as being low in resist solubility. By this configuration, the resist can further be suppressed in degradation of its patterning property, and can produce a fine resist pattern in a stable manner.

The immersion fluid for immersion lithography is preferably given as a liquid having a small viscosity. By this configuration, the bubble formation in the process of filling a space between the film to be illuminated and a projection lens in a light exposure equipment can be suppressed in a more exact manner. As a result, patterning by light exposure can be proceeded in a more stable manner.

Paragraphs below will explain deuterated dialkyl sulfoxide. Deuterated dialkyl sulfoxide is a compound having at least one hydrogen atom in dialkyl sulfoxide substituted by deuterium atom(s). So far as being characterized like this, the compound may be such as having all hydrogen atoms in dialkyl sulfoxide substituted by deuterium atoms, or may be such as having only a part of hydrogen atoms substituted by deuterium atoms. The alkyl group in the dialkyl sulfoxide may be straight or may be cyclic, and still may have branched chain(s). Two alkyl groups in dialkyl sulfoxide may be same or may be different.

Deuterated dialkyl sulfoxide is preferably a compound containing a lower alkyl group having 1 to 3 carbon atom(s) in the molecular structure there of, in view of suppressing fluctuation of refractive index in the immersion fluid ascribable to fluctuation in steric configuration of the alkyl groups. It may also be given as a compound in which one or more hydrogen atom(s) in the lower alkyl group are deuterated. This sort of deuterated dialkyl sulfoxide can be exemplified by compounds expressed by the formula (1) below:

R—SO—R (1)

(where, in the formula (1), two “R”s are the same straight-chain alkyl groups having 1 to 3 carbon atom(s) and containing one or more deuterium atom(s)).

By configuring the immersion fluid for immersion lithography as containing the compound expressed by the formula (1), balance between the refractive index and the absorbance can further be improved.

Compounds expressed by the formula (1) can specifically be exemplified by deuterated dialkyl sulfoxide, including deuterated dimethyl sulfoxide, deuterated diethyl sulfoxide, deuterated di-(n-propyl) sulfoxide, deuterated diisopropyl sulfoxide and deuterated dicyclopropyl sulfoxide.

Of these, deuterated dimethyl sulfoxide is preferably used, in view of balance between the refractive index and the absorbance. More specifically, deuterated dimethyl sulfoxide can be exemplified by D₃CSOCD₃, D₂HCSOCHD₂ and DH₂CSOCH₂D, wherein D₃CSOCD₃ is particularly preferable.

The immersion fluid for immersion lithography of the present invention may be composed of a single species of the above-described deuterated dialkyl sulfoxide, or may contain a plurality of species of deuterated dialkyl sulfoxide compounds. The immersion fluid for immersion lithography may be configured as being composed of deuterated dialkyl sulfoxide.

By configuring deuterated dialkyl sulfoxide as being composed of a single species of deuterated dialkyl sulfoxide, a local variation in the refractive index in the immersion fluid for immersion lithography can be suppressed. As a result, pattern formation by light exposure, for example, can be proceeded in a more stable manner over the entire surface of the substrate, such as wafer.

The immersion fluid for immersion lithography of the present invention may contain any compounds other than deuterated dialkyl sulfoxide, wherein a configuration mainly containing deuterated dialkyl sulfoxide is preferable.

In this context, “mainly containing deuterated dialkyl sulfoxide” means that other components may be contained up to an amount not causative of local variation in the refractive index of the fluid, and therefore unlikely to inhibit stable patterning. For example, the immersion fluid for immersion lithography of the present invention may be given as a fluid containing deuterated dialkyl sulfoxide up to an amount of 95% by weight or more, more preferably 98% by weight or more, and still more preferably 99% by weight or more.

For the case where the immersion fluid for immersion lithography of the present invention contains any compound other than deuterated dialkyl sulfoxide, such other compound may be a deuterium-containing compound.

The immersion fluid for immersion lithography of the present invention, containing deuterated dialkyl sulfoxide, has a sufficiently small absorbance, has an excellent photochemical stability, and has a large refractive index at the wavelength of light exposure. With these characteristics, it can conveniently be used as an immersion fluid having a high refractive index, a low absorbance, and an excellent photochemical stability, even under the wavelength of light exposure of 250 nm or shorter.

The immersion fluid for immersion lithography of the present invention is well balanced between high transparency and excellent photochemical stability, and is therefore especially suitable for use, for example, in vacuum ultraviolet photolithography.

The immersion fluid for immersion lithography of the present invention is used as a fluid medium which provides therein a passageway of exposure light in an immersion lithography equipment. The immersion fluid for immersion lithography herein is supplied typically between a projection lens, composing a part of an optical projection system, and a substrate such as wafer. By illuminating a mask with exposure light, and by guiding the light to the surface of the substrate through the immersion fluid for immersion lithography to the surface of the substrate, a pattern of the mask can be transferred onto the surface of the substrate.

The immersion fluid for immersion lithography of the present invention is applicable to a projection exposure equipment based on the immersion method, used for transferring a mask pattern onto a photosensitive substrate in lithographic process for manufacturing, for example, semiconductor devices, imaging devices (CCD, etc.), liquid crystal display devices, thin film magnetic heads and so forth.

Embodiments of the present invention have been described merely as examples of the present invention, without being precluded from adopting various configurations other than those described above.

### EXAMPLES

Paragraphs below will further specifically explain the present invention referring to Examples, without limiting the present invention to these Examples. Absorbance and refractive index in Examples below were measured at 23 degrees centigrade. Absorbance was measured using the above-described measuring instrument, with a cell thickness of 1 cm. Refractive index was measured by UV-VASE (Vacuum Ultraviolet Variable Angle Spectroscopic Ellipsometry) with a cell thickness of 1 cm.

### Example 1

Absorbance of deuterated dimethyl sulfoxide (heavy dimethyl sulfoxide:CD₃SOCD₃) (purity=99.8% by weight) measured at 193 nm was 0.295 cm⁻¹. The refractive index measured at 193 nm was 1.638.

### Comparative Example 1

Absorbance of pure water (purity=100% by weight) measured at 193 nm was 0.093 cm⁻¹. The refractive index measured at 193 nm was 1.433.

### Comparative Example 2

Absorbance of deuterium oxide (D₂O) (purity=99.90% by weight) measured at 193 nm was 0.014 cm⁻¹. The refractive index measured at 193 nm was 1.400.

### Comparative Example 3

Absorbance of dimethyl sulfoxide (purity=99% by weight) measured at 193 nm was 1.494 cm⁻¹. Refractive index measured at 193 nm was 1.665.

From the results of Example 1 and Comparative Example 3, it is found that deuterated dimethyl sulfoxide in Example 1 is more excellent in transparency at 193 nm as compared with dimethyl sulfoxide in Comparative Example 3, although the refractive indices are equivalent. It is also found that deuterated dimethyl sulfoxide in Example 1 has a refractive index larger than that of pure water in Comparative Example 1 and deuterium oxide in Comparative Example 2.

It is apparent that the present invention is not limited to the above embodiment, that may be modified and changed without departing from the scope and spirit of the invention.

What is claimed is:

1. An immersion fluid used for optical projection lithography based on the immersion method, containing a deuterated dialkyl sulfoxide.

2. The immersion fluid used for optical projection lithography as claimed in claim 1, wherein said deuterated dialkyl sulfoxide contains an alkyl group having 1 to 3 carbon atom(s), in the molecular structure thereof.

3. The immersion fluid used for optical projection lithography as claimed in claim 1, wherein said deuterated dialkyl sulfoxide is a compound expressed by the formula (1) below:
R—SO—R (1)
(where, two “R”s in the formula (1) express the same straight-chain alkyl groups having 1 to 3 carbon atom(s) and containing one or more deuterium atom(s)).

4. The immersion fluid used for optical projection lithography as claimed in claim 1, wherein said deuterated dialkyl sulfoxide is deuterated dimethyl sulfoxide.

5. The immersion fluid used for optical projection lithography as claimed in claim 1, having a refractive index of 1.6 or larger for light with a wavelength of 193 nm.

6. A method of optical projection lithography irradiating a mask with exposure light and guiding the light through a fluid medium to the surface of a substrate, to thereby transfer a pattern of said mask to the surface of said substrate,
wherein said fluid medium is an immersion fluid for immersion lithography, containing a deuterated dialkyl sulfoxide.
